(19) United States
(12) Patent Application Publication
(10) Pub. No.: US 2014/0000804 A1
(43) Pub. Date: Jan. 2, 2014

(54) FIXING TECHNOLOGY FOR COMPONENT ATTACH

(71) Applicants: Han Kong Looi, Singapore (SG); Cheng-hai Cheh, Singapore (SG)

(72) Inventors: Han Kong Looi, Singapore (SG); Cheng-hai Cheh, Singapore (SG)

(73) Assignee: STMicroelectronics Pte Ltd., Singapore (SG)

(21) Appl. No.: 13/539,994

(22) Filed: Jul. 2, 2012

(51) Int. Cl. B32B 38/18; B32B 37/12

(52) U.S. Cl. 156/275.5; 156/379.6

(57) ABSTRACT

A pick and place system with an integrated light source to partially cure a light-curable adhesives onto which components have been placed. After a light-curable adhesive in liquid or low viscosity form is applied to a location on a substrate, a pick-and-place head uses a vacuum introduced to its nozzle-like opening to pick a component and place it on to the light-curable adhesive. The pick-and-place head then transmit an appropriate light through the same nozzle-like opening to at least partially cure the adhesive. The component becomes, therefore, at least partially fixed to the substrate and will not shift as the substrate is moved.

### BACKGROUND

1. Technical Field

The present disclosure is directed to methods and apparatus of using light to fix a component placed over light-curable adhesives during assembly.

2. Description of the Related Art

Some semiconductor assembly operations are performed in stages in various locations in a building. The mounting or bonding of discrete components to a substrate requires transferring or moving the substrate between several stations.

A pick-and-place system 20, as illustrated in FIG. 1, uses the application of vacuum from a vacuum delivery source 22 through a vacuum path 24. The vacuum enables the pick-and-place head 30 to pick up a component 26 and place it onto its desired location on the substrate 28. The vacuum delivery source 22 then removes the vacuum and moves the vacuum probe to pick up the next component, and repeats the process. The pick-and-place system 20 generally uses linear and rotary actuator system to move the pick-and-place head 30. One example of a pick-and-place system is disclosed in U.S. Pat. No. 7,484,782.

Semiconductor manufacturers often use light-curable adhesives as a means to bond a component to a substrate, because it offers tremendous benefits in certain situations. The light-curing process for these adhesives is relatively fast as most light-curable adhesives cure fully in less than 30 seconds, thereby allowing shorter cycle time, increased capacity, and better automation. Further, light-curable adhesives create strong bond strength and can bond dissimilar substrates. Light-curable adhesives are also environmentally sensitive since they can be cured by solvent-free photopolymerization, and the energy required for curing is lower than other technologies. Light-curable adhesives are often preferred for process automation as they do not cure unless exposed to light, and they do not get cured gradually during preservation. Light-curable adhesives are used in many heat-sensitive electronics since the processing time is short, allowing control over the rise of temperature of the target object. Ultraviolet (UV) light-curable adhesive, also known as UV glue, is one example of light-curable adhesives.

UV curing is the process of changing a monomer (liquid) to a polymer (solid) with the exposure to UV light. Generally, a UV light curable adhesive consists of monomer, oligomer, photopolymerization initiator and various additives. The photopolymerization initiator is excited by the absorption of UV light and reacts with other components through decomposition to eventually change the material exposed to the UV light from liquid to solid. Different photopolymerization initiator reacts to different ranges of UV light, so a UV light is selected to match the adhesive to be cured. UV-A is the most common light used for curing UV light adhesives. When used to cure a UV adhesive, a UV radiation is generally measured by its irradiation intensity per unit area (for example, in mW/cm2). The amount of UV exposure (Intensity x Irradiation time) needed for curing depends on the material itself and generally, higher intensity leads to faster cure.

Other light-curable adhesives can be used as well, such as those curable through exposure to visible light.

A light-curing is usually a later stage of the electronics product assembly line. Once components have been placed on a substrate, the substrate is moved into a closed light-curing chamber or through a light-curing conveyor. During this stage, the light-curable adhesive is exposed to the appropriate curing light and become fully cured.

FIG. 2A illustrates a component 34 placed on uncured light-curable adhesive 36 on a substrate 28. Due to the low viscosity of the uncured adhesive 36, the component 34 is prone to shifting when a pick and place head releases and moves away from the component 34 and when the substrate 28 is moved from one stage to another stage. FIG. 2B shows the component 34 that has shifted over the uncured light-curable adhesive 36. Any movement of the pick and place head or of the substrate 28 may be enough to cause the component 34 to shift. Currently, great care must be taken when tuning process parameters and when moving a substrate from the pick-and-place stage to the curing stage in order to avoid disturbing, shifting, or otherwise moving the components already placed on the adhesives on the substrate. If full curing is carried out with one or more components shifted, yield is reduced because the shifted components will not be fixed in the right location. In cases where hundreds of components are placed on a substrate, there is no means or time to re-set each component to its proper location before curing.

### BRIEF SUMMARY

The present disclosure relates to fixing a component to a substrate to prevent the component from shifting. A light source is coupled to a pick-and-place head, and the light is transmitted on a component placed over a light-curable adhesive. As the light-curable adhesive begins to cure, it holds the component in place on the substrate. The light is transmitted through the opening of an aperture through which a vacuum is introduced to pick and place a component.

### BRIEF DESCRIPTION OF THE SEVERAL VIEWS OF THE DRAWINGS

FIG. 1 illustrates a common pick-and-place system that uses vacuum to pick and place components.

FIG. 2A illustrates a component that has been placed over an uncured light-curable adhesive on a substrate.

FIG. 2B illustrates a component shifted from its original position over an uncured light-curable adhesive after the substrate is moved.

FIG. 3A and FIG. 3B illustrate one embodiment of the disclosure.

FIG. 4 illustrates a cross section of an enlarged view of one embodiment of the pick- and-place head of this disclosure.

FIG. 5 illustrates another embodiment of the disclosure.

FIG. 6 illustrates an embodiment of a method for partially fixing a component in the disclosure.

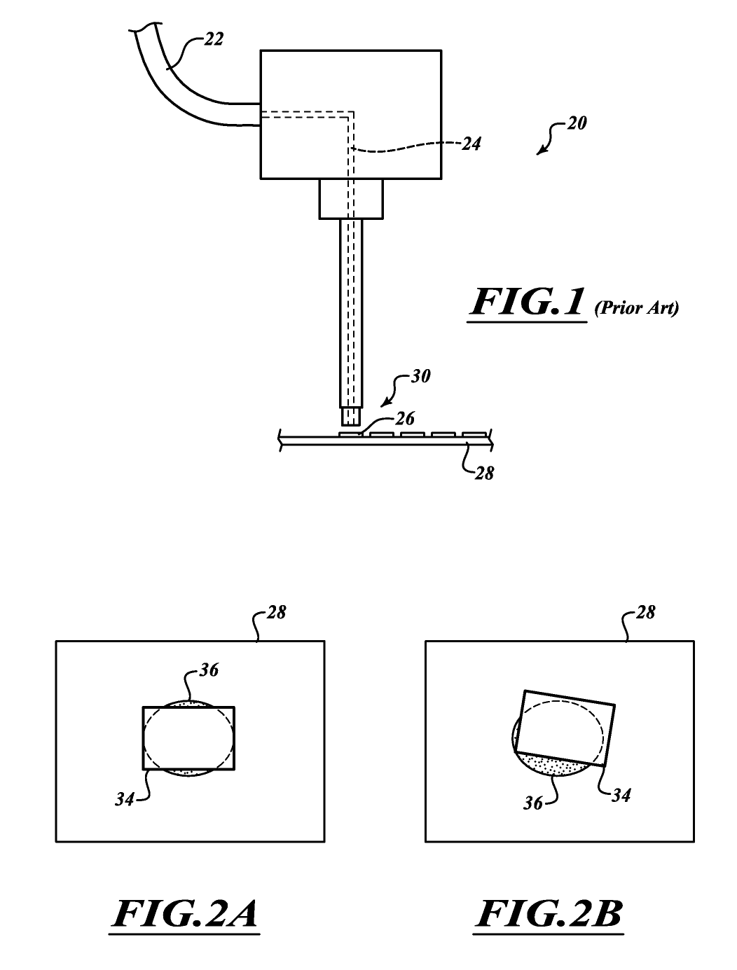

### DETAILED DESCRIPTION

In the following description, certain specific details are set forth in order to provide a thorough understanding of various embodiments of the disclosure. However, one skilled in the art will understand that the disclosure may be practiced without these specific details. In some instances, well-known structures associated with semiconductor manufacturing and assembly process have not been described in detail to avoid obscuring the description of the embodiments of the present disclosure.

Unless the context requires otherwise, throughout the specification and claims that follow, the word “comprise” and variations thereof, such as “comprises” and “comprising” are to be construed in an open, inclusive sense, that is, as “including, but not limited to.”

Reference throughout this specification to “one embodiment” or “an embodiment” means that a particular feature, structure, or characteristic described in connection with the embodiment is included in at least one embodiment. Thus the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the drawings, identical reference numbers identify similar features or elements. The size and relative positions of features in the drawings are not necessarily drawn to scale.

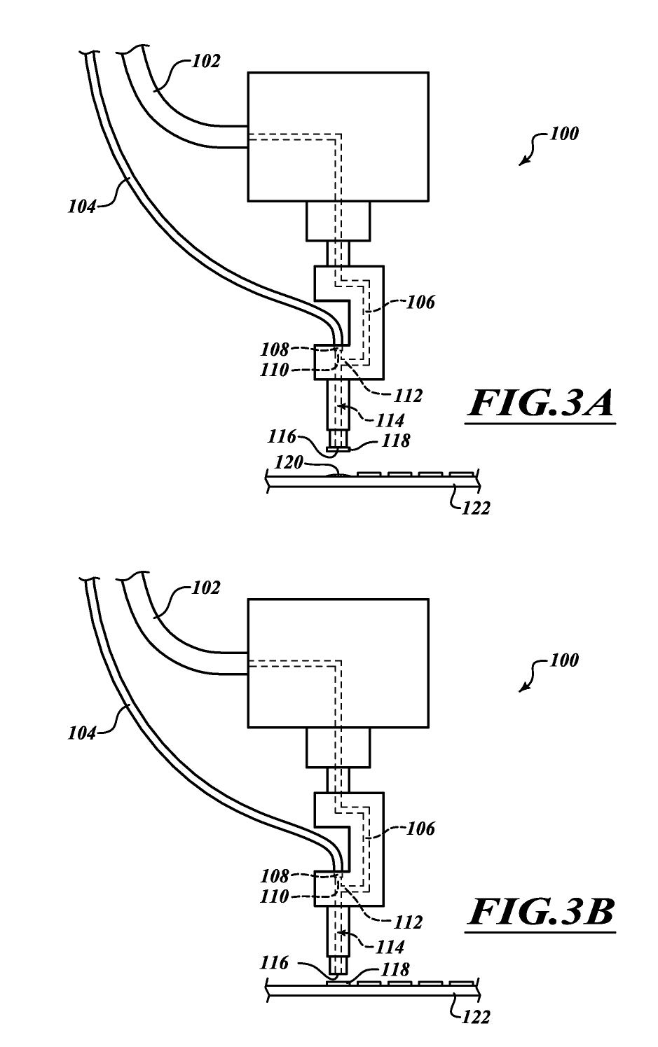

In FIGS. 3A and 3B, an embodiment of a pick-and-place head 100 is shown at different times during a pick and place process. A vacuum delivery source 102 introduces a vacuum to the vacuum path 106 coupled to an aperture 114 in the pick-and-place head 100 through a first opening 112 on the aperture 114. This allows the vacuum to be introduced through a second opening 116 of the aperture 114 to create a suction force that enables the pick-and-place head to pick up a component 118. The term “component” as used herein is meant in the broadest sense and includes individual pieces, subassemblies, assembled parts, system and other devices that are put into a final product, on a substrate, or on printed circuit boards. An optical fiber 104 is coupled to a third opening 110 of the aperture 114, the optical fiber acting as a waveguide for a light from a light source at one end of the optical fiber to the tip 108 of the optical fiber 104. The light from the tip 108 of the optical fiber 104 in the third opening 110 of the aperture 114, passes through the aperture 114, and is output from the second opening 116 of the aperture 114. The first opening 112 of the aperture 114 is located between the third opening 110 and the second opening 116.

To pick a component, the pick-and-place head 100 is first positioned over the component 118, then it is lowered such that the second opening 116 comes in contact with the component 118. A vacuum is introduced to the vacuum path 106, creating a suction force that causes the component 118 to be affixed the second opening 116. The pick-and-place head 100 is then raised up and positioned to the location onto which the component is to be placed, the location where light-curable adhesive 120 is already applied on a substrate 122. With the vacuum still introduced, the pick-and-place head 100 is lowered toward the substrate 122 until the component 118 that is affixed to the second opening 116 comes to rest on the light-curable adhesive 120. FIG. 3A shows the component 118 before it is placed onto the light curable adhesive.

A light is subsequently directed through the optical fiber 104 and the tip 108 of the optical fiber transmits the light through the second opening 116 of the aperture 114 on component 118 for a selected period of time. This causes the light-curable adhesive under the component 118 to begin to cure and hold the component 118 in place. FIG. 3B illustrates the component 118 already held in place on the substrate 122 with the adhesive 120 at least partially cured.

The required light exposure to cure a light-curable adhesive depends on the light intensity and the adhesive material itself. UV adhesives generally need between 250 ms and 1 second of UV light exposure to become partially cured, and between 5 seconds and 30 seconds to become fully cured. Depending on the type of adhesive and the intensity of the light, the period of light exposure is selected to be as short as practical in order to ensure that the component is at least partially fixed so that it does not shift or become otherwise disturbed when the substrate is moved to the next stage. In one embodiment, a light is transmitted for 500 ms to partially cure the light-curable adhesive. In another embodiment, a light is transmitted for 5 to 30 seconds to fully cure the light-curable adhesive. Having the light-curable adhesive fully cured during the pick-and-place stage may eliminate the need to move the substrate to another stage for additional curing, and this may be desirable when there are only a few components to be bonded to a substrate. However, if there are hundreds of components to be bonded on a substrate, the cumulative time it takes to fully cure each component individually may be prohibitive. For 400 components, for example, it would take more than 30 minutes of curing. It may be more efficient in this case to only partially cure the light-curable adhesive after each component is placed, then move the substrate to the next stage to fully cure all the components concurrently. In this later approach, individual partial curing of all 400 components would take less than 4 minutes, and the full curing for the whole substrate would be in the range of 5 to 30 seconds, depending on the type of adhesive and the intensity of the light. The specific numbers set forth here are meant to be examples as it is known in the art that the curing profile, thus curing time, for a light-curable material depends on the light intensity used.

At the conclusion of at least partial curing of the light-curable adhesive, the pick-and-place head 100 may be moved away from the component 118 to pick and place another component. FIG. 3B illustrates the component 118 placed on the substrate.

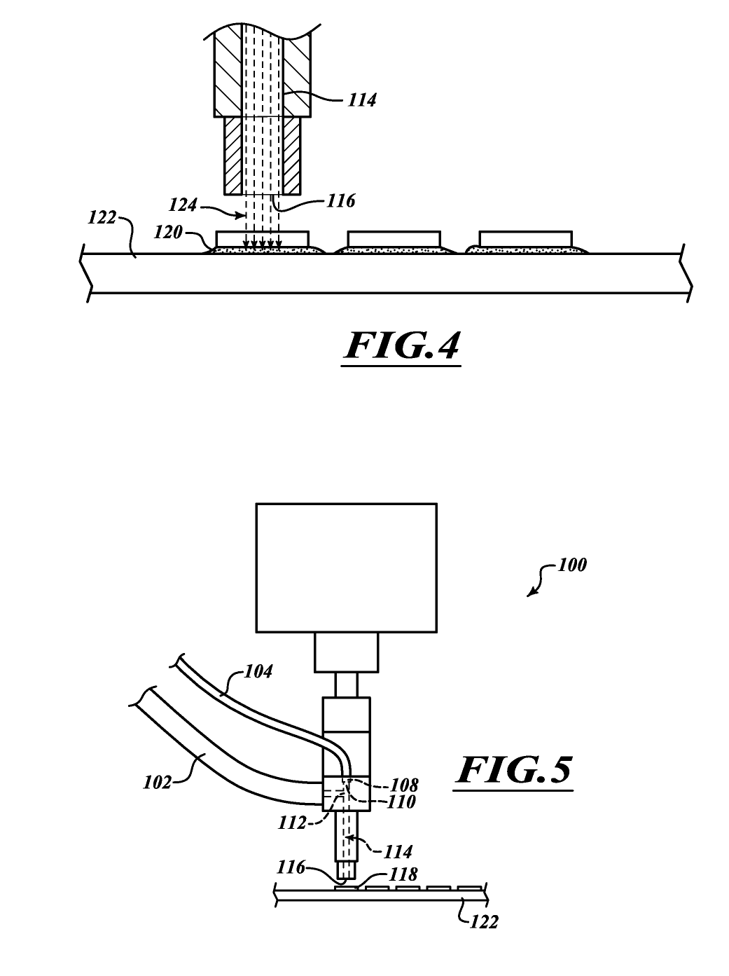

FIG. 4 is the enlarged view of the light 124 being transmitted out of the second opening 116 of the aperture 114 of the pick-and-place head 100 towards the component 118 to partially cure the light-curable adhesive 120. In a preferred embodiment, the light 124 is transmitted when the second opening 116 is still adjacent to the component 118 and the pick-and-place head has not moved away from the component 118. In some cases, the vacuum may still be applied when the light is transmitted. In an alternative embodiment, the light 124 is transmitted after the vacuum is released and the pick-and-place head 100 has distanced itself from the component 118, creating a small space between the second opening 116 and the component 118.

The optical fiber 104 may be a fiber optic strand for carrying an ultraviolet light or other visible lights. There are a variety of light-curable adhesives, and each of them may require a light of certain wavelength for curing. Different light sources, therefore, may be used and the most appropriate optical fiber 104 may be selected accordingly.

There are at least two possible techniques to combine the vacuum delivery source and the optical fiber. In one embodiment, illustrated in FIG. 3A and 3B, the vacuum delivery source 102 is coupled to the vacuum path 106 at a location away from the pick-and-place head, the vacuum path 106 is shown traversing the length of the pick-and-place body from the vacuum delivery source 102, through the “C” arm, to the first opening 112 of the aperture 114. In this combination, the pick-and-place tool may control the vacuum delivery. In an alternative embodiment, as illustrated in FIG. 5, the vacuum delivery source 102 is coupled to the vacuum path 106 only to the pick-and-place head 100. The vacuum path 106 may be short and does not traverse the length of the pick-and-place body. In this embodiment, a vacuum delivery controller external to the pick-and-place tool may be used. One skilled in the art understands that there are other alternative techniques to combine the vacuum delivery source and the optical fiber in a pick-and-place tool and they fall within the scope of this disclosure.

In a preferred embodiment, a UV light source is guided over an optical fiber strand that is 6 mm in diameter. The optical fiber strand is coupled to the third opening of the aperture at a distance of 3 mm from the second opening 116 of the aperture 114. A diameter of the second opening 116 of the aperture 114 may be selected to provide a desired light intensity. The following table shows some of the possible diameters of the second opening 116 and the associated intensities of the light leaving the second opening 116 when the UV light source is transmitted at 90% intensity.

| Diameter (mm) | Intensity (mW) |
|---|---|
| 0 | 0 |
| 0.5 | 40 |
| 1 | 600 |
| 1.5 | 900.4 |
| 2 | 1530.5 |
| 2.5 | 1560 |

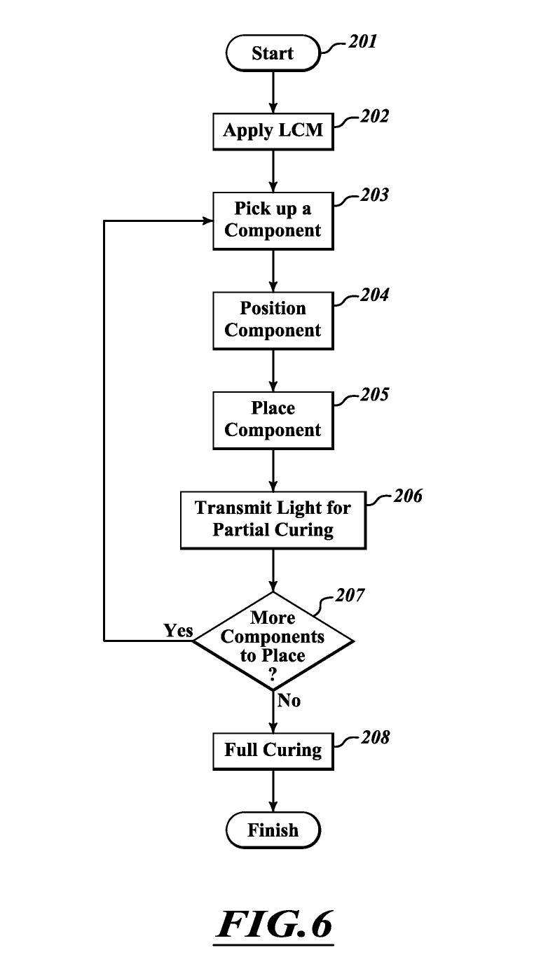

FIG. 6 illustrates one embodiment of a method in the disclosure. In this embodiment, a method starts, step 201, with the application of uncured light-curable adhesive to a location on a substrate, step 202. A UV adhesive is an example of light-curable adhesive. Generally the uncured light-curable adhesive is applied to multiple locations on a substrate. A vacuum is then introduced, step 203, through an aperture in a pick-and-place head to create suction force to pick up a component. The pick-and-place head positions the component, step 204, over at least one location on the substrate and places the component, step 205, onto the light-curable adhesive at the location. Light is transmitted, step 206, through the aperture onto the just-placed component for a length of time selected to at least partially fix the component so it does not shift or otherwise disturbed when the substrate is moved. In a preferred embodiment, an ultraviolet light is transmitted for 500 ms or less to only partially cure a UV adhesive. The aperture through which the light is transmitted is the same aperture through which vacuum is introduced. The light may be an ultraviolet light or other visible lights. Determination is then made if there is any additional component to be placed on the substrate, step 207. If there is, the process repeats with the introduction of a vacuum, from step 203 to step 207 again. If there is no more component to place, the substrate is moved to the next stage for full curing, 208.

In an alternative embodiment, the light is be transmitted, step 206, onto the just-placed component for a length of time selected to fully cure the light-curable adhesive on which the component was placed. An ultraviolet light may be transmitted for 5 to 30 seconds to fully cure a UV adhesive. In this alternative embodiment, the substrate does not need to be moved to the next stage for full curing anymore.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An apparatus comprising:
a pick-and-place head;
an aperture extending through the pick-and-place head, the aperture having a first opening to receive a vacuum from a vacuum delivery source and a second opening acting as a nozzle through which the vacuum is applied outside the head for picking up parts;
a vacuum path through which the vacuum from the vacuum delivery source is introduced coupled to the first opening of the aperture;
an optical fiber coupled to a third opening of the aperture, the third opening of the aperture being in an optical path with the second opening acting as the nozzle; and
a light source coupled to the optical fiber and configured to transmit light out of the same nozzle as that the vacuum is applied to pick up parts.

2. The apparatus in claim 1, wherein the first opening is located between the second opening and the third opening;

3. The apparatus in claim 1, wherein the light source is an ultraviolet light source.

4. The apparatus in claim 1, wherein the light source is a visible light source.

5. The apparatus in claim 1, wherein a diameter of the second opening of the aperture is between 0.5 mm and 2.5 mm.

6. The apparatus in claim 2, wherein a diameter of the second opening of the aperture is 1 mm and 2 mm.

7. The apparatus in claim 1, wherein a distance between the third opening and the second opening of the aperture is 3 mm or less.

8. A method to at least partially fix a component to a substrate comprising:
applying a light-curable adhesive to at least a location on a substrate;
applying a vacuum through an aperture in a pick-and-place head to pick up a component;
moving the pick-and-place head with the component to be adjacent to the location of the light-curable adhesive on the substrate;
placing the component on the light-curable adhesive;
transmitting a light through the aperture in the pick-and-place head to illuminate at least some of the light-curable adhesive for a sufficient length of time to at least partially cure some of the light-curable adhesive; and
transferring the substrate to a new position with the component at least partially fixed thereto.

9. The method in claim 8, wherein the light-curable adhesive is a UV adhesive and the light transmitted through the aperture is a UV light.

10. The method in claim 8, further comprising transmitting the light through the aperture in the pick-and-place head to illuminate at least some of the light-curable adhesive for a sufficient length of time to fully cure the light curable adhesive.

11. The method in claim 8, further comprising: after placing the component, releasing the vacuum to detach the component from the pick-and-place head; and moving the pick-and-place head away from the component.

12. The method in claim 11, wherein moving the pick-and-place head is subsequent to transmitting a light.

13. The method in claim 11, wherein transmitting the light is subsequent to moving the pick-and-place head.

14. A system comprising:
a means for applying a light-curable adhesive to at least a location on a substrate;
a vacuum means for picking a component and moving the component to be adjacent to the location of the light-curable adhesive on the substrate;
a vacuum means for placing the component on the light-curable adhesive;
a means for transmitting a light to illuminate at least some of the light-curable adhesive for a sufficient length of time to at least partially cure some of the light-curable adhesive; and
a means for transferring the substrate to a new position with the component at least partially fixed thereto.

15. The system in claim 14, wherein the means for transmitting a light comprises: a light source; an optical fiber; and an aperture having a third opening coupled to the optical fiber and a second opening being in an optical path with the third opening.

16. The system in claim 15, wherein a diameter of the optical fiber is 6 mm and a diameter of the second opening of the aperture is between 0.5 mm and 2.5 mm.

17. The system in claim 14, wherein the vacuum means for picking a component comprises: a vacuum delivery source; and a vacuum path coupled to a first opening of an aperture, the aperture having a second opening that acts as a nozzle through which a vacuum is applied.

18. The system in claim 17, wherein the means for transmitting a light comprises: a light source; and an optical fiber, the optical fiber coupled to a third opening of the aperture, the third opening being in an optical path with the second opening.

19. The system in claim 14, wherein the means for transmitting a light is configured to transmit the light subsequent to the placement of a component of the vacuum means for placing the component.
